(19) United States
(12) Patent Application Publication
(10) Pub. No.: US 2002/0000634 A1
(43) Pub. Date: Jan. 3, 2002

(54) Connection element

(76) Inventors: Dirk Drescher, Langebruck (DE); Wolfgang Leiberg, Dresden (DE); Rene Tews, Dresden (DE); Matthias Lehr, Dresden (DE); Alexander Ruf, Dresden (DE)

Correspondence Address: LERNER AND GREENBERG, P.A., Post Office Box 2480, Hollywood, FL, 33022-2480, US

(21) Appl. No.: 09/888,020

(22) Filed: Jun. 22, 2001

(30) Foreign Application Priority Data
Jun. 22, 2000 (DE) 100 30 445.1

(51) Int. Cl. H01L 29/00

(52) U.S. Cl. 257/501; 257/499; 257/506; 257/508

(57) ABSTRACT

The connection element in an integrated circuit has a layer structure arranged between two conductive structures. The layer structure has a dielectric layer which can be destroyed by application of a predetermined voltage. At least one conductive structure is composed of tungsten. The conductive structure adjoins a conductive layer made of tungsten or a tungsten compound, which is a constituent part of the layer structure and which adjoins the dielectric layer.

### BACKGROUND OF THE INVENTION

Field of the Invention

The invention lies in the integrated technology field and pertains, more specifically, to a connection element in an integrated circuit with a layer structure arranged between two conductive structures. The layer structure has a dielectric layer which can be destroyed by application of a predetermined voltage.

Connection elements of this type are used in integrated circuits in order, for example, to activate redundant memory cells in DRAMs. Furthermore, connection elements of this type can be used in order to write identifiers to chips or in order to change functionalities of chips in a targeted manner. In particular, connection elements of this type can be used as programmable connection elements in the context of FPGAs (field-programmable gate arrays).

In this case, the connection elements can be designed as fuse circuits or antifuse circuits. A fuse circuit has a structure via which a current flows as long as the structure is intact. The structure can be destroyed by irradiation with laser light or the application of a voltage, with the result that current can then no longer flow.

A connection element designed as an antifuse circuit typically has a layer structure having a dielectric layer which is arranged between two conductive layers.

With the dielectric layer intact, no current flows via the connection element. Only when a predetermined electric voltage is applied to the connection element is the dielectric layer destroyed, with the result that a current can then flow.

The voltage is applied via contacts or similar structures which are led to the conductive layers of the layer structure of the connection element.

In prior art connection elements of this type, the conductive layers of the layer structure are composed of polysilicon. A contact composed of tungsten is led to at least one of the layers. In order to fabricate the contact, a contact hole is etched into an oxide layer, the conductive polysilicon layer adjoining the underside of the contact hole serving as an etch stop during the etching process.

Structures of that type have the disadvantage that high deposition temperatures are required for the deposition of the polysilicon layers. As a result of this, the tungsten which forms the contact reacts with the adjoining polysilicon layer to form WSiₓ, as a result of which an undesirably rough interface between the contact layer and the conductive layer is obtained. In particular, this can considerably impair the reliability of the connection element.

Furthermore, it is disadvantageous that the polysilicon layer must have a large layer thickness in order to obtain a reliable etch stop during the etching of the contact hole.

Finally, it is disadvantageous that polysilicon has a comparatively low conductivity, so that relatively high voltages must be applied to the connection element in order to destroy the dielectric layer.

U.S. Pat. No. 6,001,693 discloses a method for fabricating a connection element configured as an antifuse circuit. The antifuse circuit comprises a layer structure having a dielectric layer located between two metallic layers. The metallic layers each bear on an electrode.

The metallic layers are preferably composed of W, TiW, TiWN, TiN, Ti or WSiₓ. The electrodes are composed of Al.

### SUMMARY OF THE INVENTION

The object of the present invention is to provide a connection structure which overcomes the above-noted deficiencies and disadvantages of the prior art devices and methods of this general kind, and which has a high reliability in conjunction with the smallest possible topography.

With the above and other objects in view there is provided, in accordance with the invention, a connection element in an integrated circuit, comprising:

a layer structure disposed between a first conductive structure composed of tungsten and a second conductive structure;

the layer structure including a conductive layer formed of a material selected from the group consisting of tungsten and a tungsten compound and adjoining the first conductive structure, and a dielectric layer adjoining the conductive layer and configured to be destroyed by application of a predetermined voltage.

A corresponding integrated circuit formed on a substrate, the assembly comprises:

a substrate;

an interconnect disposed on the substrate;

an insulating layer disposed on the interconnect;

a first conductive layer containing tungsten disposed on the insulating layer; and

the insulating layer being configured to be destroyable by applying a predetermined voltage producing a conductive connection between the interconnect and the first conductive layer.

In other words, the connection element according to the invention has a layer structure arranged between two conductive structures. The layer structure comprises a dielectric layer and at least one conductive layer adjoining the latter.

At least one conductive structure is composed of tungsten and is led to the or one conductive layer of the layer structure, the conductive layer being composed of tungsten or a tungsten compound, in particular WN or WSix.

An essential advantage of this arrangement is that, at the interface between the conductive structure composed of tungsten and the conductive layer—composed of W, WN or WSix—of the layer structure, interface reactions which lead to roughening of the interface are largely avoided. For the case where the conductive layer is composed of WSix, WSi₂ forms at the interface until a stoichiometric equilibrium is reached, which prevents further reactions with the tungsten layer.

Moreover, the deposition temperatures of the conductive layers—according to the invention—of the layer structure are considerably lower than in the case of conductive layers made of polysilicon. As a result, homogeneous layer thicknesses are obtained during the deposition of the corresponding layers, as a result of which, in particular, degradation-resistant interfaces are obtained between the conductive layers and the structure composed of tungsten. This leads to high reliability of the connection elements.

A further advantage of the connection element according to the invention is that the conductive layers composed of tungsten or a tungsten compound have a high conductivity, so that low voltages already suffice to destroy the adjoining dielectric layer.

In an advantageous embodiment, the structure composed of tungsten is formed by a contact. In order to fabricate the contact, a contact hole is etched into an oxide layer as far as the conductive layer adjoining the contact, through which tungsten is deposited into the contact hole.

Since the conductive layer is composed of W, WN or WSix, it forms a reliable etch stop during the etching process. Consequently, the conductive layer can have a small layer thickness, as a result of which the layer structures obtain a small topography. Moreover it is advantageous that there is a high degree of etching selectivity between the oxide layer and the conductive layer composed of W, WN or WSix, as a result of which high process reliability is obtained during the performance of the etching process.

In accordance with an advantageous feature of the invention, the layer structure is formed between a contact made of tungsten and an interconnect made of tungsten. The conductive layer composed of W, WN or WSix adjoins the contact. A conductive layer composed of W, WN or WSix may likewise adjoin the interconnect. As an alternative, the conductive layer may also be composed of polysilicon without major losses of connection element reliability.

In both cases, the layer structure has two conductive layers between which the dielectric layer is located.

In accordance with a particularly simple feature of the invention, the layer structure has only one conductive layer made of W, WN or WSix and a dielectric layer. In this case, the conductive layer adjoins the contact made of tungsten, while the dielectric layer is seated directly on the interconnect made of tungsten. This results in a particularly small topography of the connection element.

Other features which are considered as characteristic for the invention are set forth in the appended claims.

Although the invention is illustrated and described herein as embodied in a connection element, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic view of a first exemplary embodiment of the connection element according to the invention;

FIG. 2 is a diagrammatic view of a second exemplary embodiment of the connection element according to the invention; and

FIG. 3 is a diagrammatic view of a third exemplary embodiment of the connection element according to the invention.

### DESCRIPTION OF THE PREFERRED EMBODIMENTS

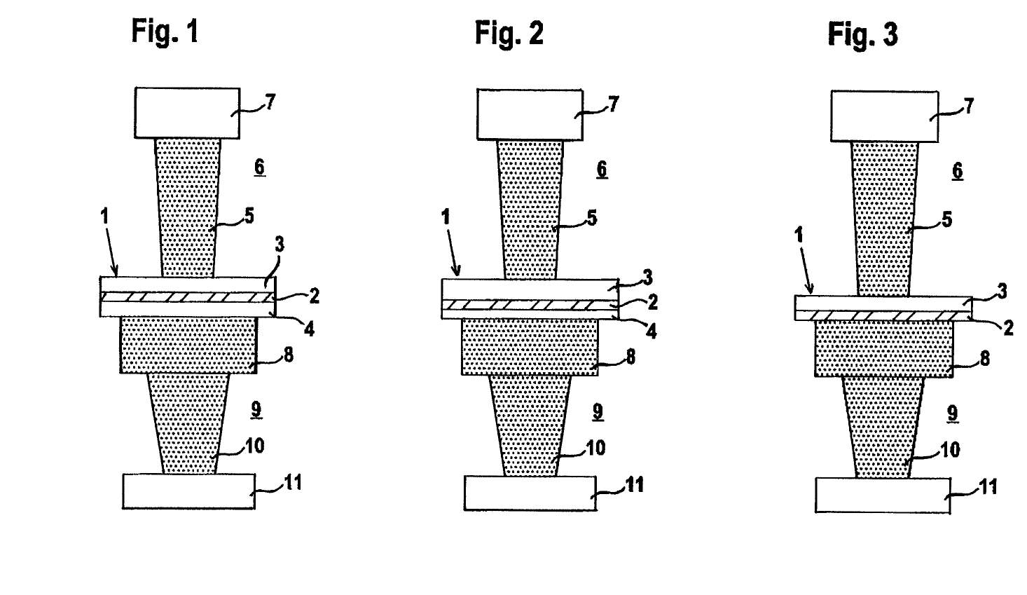

Referring now to the figures of the drawing in detail and first, particularly, to FIG. 1 thereof, there is seen a first exemplary embodiment of a connection element configured as an antifuse circuit.

The connection element has a layer structure 1 with a dielectric layer 2.

With the dielectric layer 2 intact, no current flows via the connection element. The dielectric layer 2 can be destroyed by application of a predetermined voltage, so that an electric current can then flow via the connection element. Such connection elements designed as antifuse circuits are used in integrated circuits for example in order to activate redundant memory cells in DRAMs. In addition, the connection elements can be used for writing identifiers to chips or for changing functionalities of chips. In particular, the antifuse circuits can be used as programmable connection elements for field-programmable gate arrays (FPGAs).

In the exemplary embodiment illustrated in FIG. 1, the layer structure 1 has, in addition to the dielectric layer 2, a first conductive layer 3 applied on the dielectric layer 2. According to the invention, this first conductive layer 3 is composed of tungsten or a tungsten compound. The tungsten compound is preferably WN (tungsten nitride) or WSix (tungsten silicide). Moreover, a second conductive layer 4 is provided, on which the dielectric layer 2 is applied. In the present exemplary embodiment, the second conductive layer 4 is composed of polysilicon.

The dielectric layer 2 itself is preferably composed of Si₃N₄. As an alternative, SiO₂ can also be used for the dielectric layer 2.

The top side of the layer structure 1 is adjoined by a first conductive structure, which, in the present exemplary embodiment, is formed by a contact 5 composed of tungsten. The contact 5 runs in an oxide layer 6 and, at its top side, adjoins an interconnect 7 which runs in a first interconnect plane and is composed of aluminum in the present exemplary embodiment.

The underside of the layer structure 1 is adjoined by a second conductive structure formed by a second interconnect 8 composed of tungsten. This interconnect 8 runs in an interconnect plane which runs below the first interconnect plane.

From the second interconnect 8, a contact 10 made of tungsten and running in a second oxide layer 9 leads to a silicon layer 11, wherein integrated circuits are incorporated.

The layer structure 1 on the second interconnect 8 is preferably produced by means of CVD processes or PVD processes. In this case, in order to produce the individual layers, preferably only CVD methods or only PVD methods are used in order that the process control for the deposition of the individual layers is configured as simply as possible. In particular, the individual layers can be produced by means of LPCVD (low-pressure CVD) methods.

It is particularly advantageous that the deposition of the first conductive layer 3 composed of W, WN or WSix can take place at low deposition temperatures. For the case where the first conductive layer 3 is composed of WSix, the deposition temperature is about 550° C. In comparison with this, deposition temperatures for the deposition of polysilicon layers are typically 660° C. As a result, a particularly smooth interface is obtained between the first conductive layer 3 and the adjoining contact 5 composed of tungsten.

At the interface between the second conductive layer 4 composed of polysilicon and the underlying interconnect 8 made of tungsten, a reaction takes place wherein tungsten reacts with silicon to form WSix, which results in a roughening of the interface. This necessitates a relatively high layer thickness of the second conductive layer 3.

By contrast, at the interface between the contact 5 composed of tungsten and the first conductive layer 3, no such reaction takes place, since that layer, according to the invention, is composed of W, WN or WSix. Accordingly, the first conductive layer 3 can have a very small layer thickness, without impairing the reliability of the connection element 1.

In order to fabricate the contact 5, firstly a contact hole is etched into the oxide layer 6. The opening is formed down to the first conductive layer 3. In this case, it is particularly advantageous that the first conductive layer 3 composed of W, WN or WSix forms a reliable etch stop for the etching process and, in addition, has a high degree of etching selectivity with respect to the adjoining oxide layer 6. As a result, reliable process control of the etching process is obtained even for a very thin first conductive layer 3.

Referring now to FIG. 2, there is shown a second exemplary embodiment of the connection element according to the invention. This connection element has the same construction as the connection element shown in FIG. 1. In particular, the connection element in accordance with FIG. 2 has a layer structure 1 having a dielectric layer 2 whose top side is adjoined by the first conductive layer 3 and whose underside is adjoined by the second conductive layer 4.

In contrast with the exemplary embodiment in accordance with FIG. 1, in this case the second conductive layer 4 is composed of W, WN or WSix in the same way as the first conductive layer 3.

As a result, an undesirable interface reaction between silicon and tungsten is also avoided at the interface between the second conductive layer 4 and the interconnect 8 composed of tungsten. Consequently, the layer thickness of the second conductive layer 4 can be chosen to be considerably smaller compared with the exemplary embodiment illustrated in FIG. 1.

Since both conductive layers 3, 4 of the layer structure 1 are composed of W, WN or WSix and thus have a greatly increased conductivity compared with a layer made of polysilicon, in this exemplary embodiment a particularly low voltage applied via the conductive structures suffices to destroy the dielectric layer 2.

Referring now to FIG. 3, there is shown a third exemplary embodiment of the connection element according to the invention. This connection element has essentially the same construction as the connection element in accordance with FIG. 1.

In contrast with the exemplary embodiment in accordance with FIG. 1, in this case the layer structure 1 merely comprises the first conductive layer 3 and the adjoining dielectric layer 2. These layers 2, 3 are formed identically to the corresponding layers 2, 3 of the layer structure 1 in accordance with FIG. 1.

The first conductive layer 3 made of W, WN or WSix once again adjoins the contact 5 composed of tungsten. By contrast, the second interconnect 8 does not adjoin a second conductive layer 4 but rather directly adjoins the dielectric layer 2.

It is advantageous in this case that a particularly small topography of the connection element is obtained by virtue of the small number of layers in the layer structure 1.

What is problematic in this case is that the dielectric layer 2 is applied directly to the interconnect 8. In this case, under unfavorable circumstances, the adhesion forces at the interface may possibly be insufficient to obtain sufficient adhesion of the dielectric layer 2 on the interconnect 8.

In order to rule out such possible problems in the preliminary stages, the surface of the interconnect 8 is advantageously roughened somewhat before the deposition of the dielectric layer 2. Sputter-clean methods are preferably used in this case. Afterward, the dielectric layer 2 is deposited preferably by means of a PVD method.

We claim:

1. A connection element in an integrated circuit, comprising:
a layer structure disposed between a first conductive structure composed of tungsten and a second conductive structure;
said layer structure including a conductive layer formed of a material selected from the group consisting of tungsten and a tungsten compound and adjoining said first conductive structure, and a dielectric layer adjoining said conductive layer and configured to be destroyed by application of a predetermined voltage.

2. The connection element according to claim 1, wherein said tungsten compound is a compound selected from the group consisting of WN and WSix.

3. The connection element according to claim 1, wherein said dielectric layer is formed of a material selected from the group consisting of SiN₃ and SiO₂.

4. The connection element according to claim 1, wherein said layer structure comprises said conductive layer and said dielectric layer disposed thereon.

5. The connection element according to claim 1, wherein said conductive layer is a first conductive layer and said layer structure is formed of said first conductive layer, a second conductive layer, and said dielectric layer disposed in between.

6. The connection element according to claim 5, wherein said second conductive layer of said layer structure is composed of polysilicon.

7. The connection element according to claim 1, wherein one of said conductive structures is a contact connecting said layer structure to a first interconnect.

8. The connection element according to claim 7, wherein said first interconnect is composed of aluminum.

9. The connection element according to claim 7, wherein said contact is a tungsten layer deposited in a contact hole etched into an oxide layer and reaching to said layer structure.

10. The connection element according to claim 7, wherein said second conductive structure is a second interconnect composed of tungsten.

11. The connection element according to claim 10, which further comprises a silicon layer and a contact composed of tungsten connecting said second interconnect to said silicon layer.

12. A connection element in an integrated circuit on a substrate, comprising:
a substrate;
an interconnect disposed on said substrate;
an insulating layer disposed on said interconnect;
a first conductive layer containing tungsten disposed on said insulating layer; and
said insulating layer being configured to be destroyable by applying a predetermined voltage producing a conductive connection between said interconnect and said first conductive layer.

13. The connection element according to claim 12, which further comprises a second conductive layer between said interconnect and said insulating layer, said second conductive layer containing polycrystalline, doped silicon.

14. The connection element according to claim 12, which further comprises a tungsten-containing contact on said first conductive layer.

15. The connection element according to claim 12, wherein said interconnect contains tungsten.
